(19) United States
(12) Patent Application Publication
(10) Pub. No.: US 2013/0029578 A1
(43) Pub. Date: Jan. 31, 2013

(54) MANAGING SYSTEM FOR DISSIPATING HEAT FROM SERVER GROUP

(71) Applicant: KANG-BIN WANG, Shenzhen City (CN)

(72) Inventor: KANG-BIN WANG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/525,481

(22) Filed: Jun. 18, 2012

(30) Foreign Application Priority Data
Jul. 29, 2011 (CN) 201110215710.2

(51) Int. Cl. H05K 5/02

(52) U.S. Cl. 454/184

(57) ABSTRACT

A managing system for dissipating heat from a plurality of servers, includes a control module. Each server includes a first wireless communication unit, a fan rotation speed control unit, a first fan, and a first temperature sensor. The fan rotation speed control unit and the first temperature sensor are connected to the first wireless communication unit. The fan rotation speed control unit generates a first fan rotation speed signal. The first temperature sensor generates a first temperature signal which includes a second wireless communication unit and a control unit. The control unit receives the first fan rotation speed signal and the first temperature signal. The control unit generates a first control signal. The fan rotation speed control unit adjusts the rotation speed of the first fan according to the first control signal.

### BACKGROUND

1. Technical Field

The present disclosure relates to managing systems, and particularly to a managing system for dissipating heat from a server group.

2. Description of Related Art

A server group usually includes a plurality of blade servers mounted in a server rack. Each of the plurality of blade servers can work independently and generate an amount of heat. Conventionally, each of the blade servers is individually controlled to dissipate heat. However, because the plurality of blade servers are located adjacent to each other, it is inefficient for individually controlling each blade server to dissipate heat.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a block view of an embodiment of a managing system for dissipating heat from a server group, which includes a control module and a server group.

FIG. 2 is a block view of a server of the server group of FIG. 1.

FIG. 3 is a block view of the control module of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

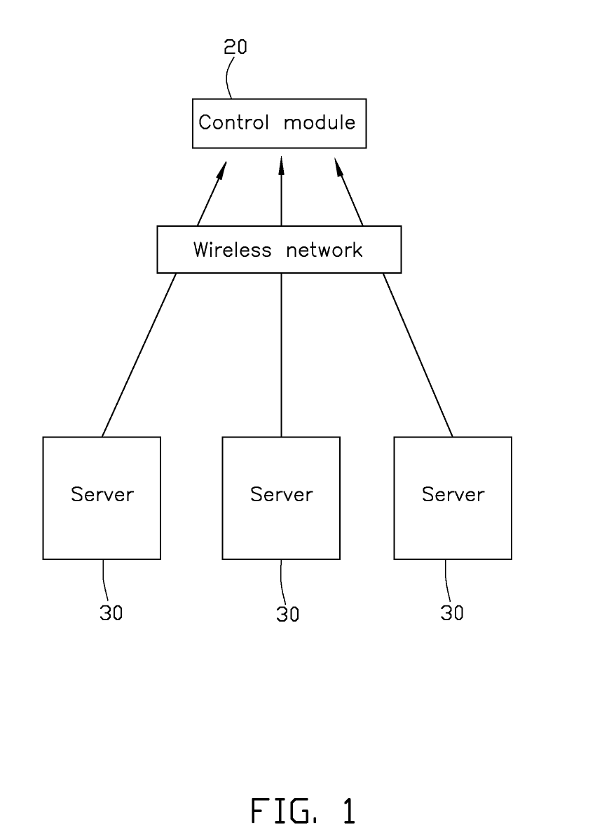

FIG. 1 illustrates an embodiment of a managing system for dissipating heat from a server group. The managing system includes a control module 20. The server group includes a plurality of servers 30, which is connected to the control module 20 via a wireless network.

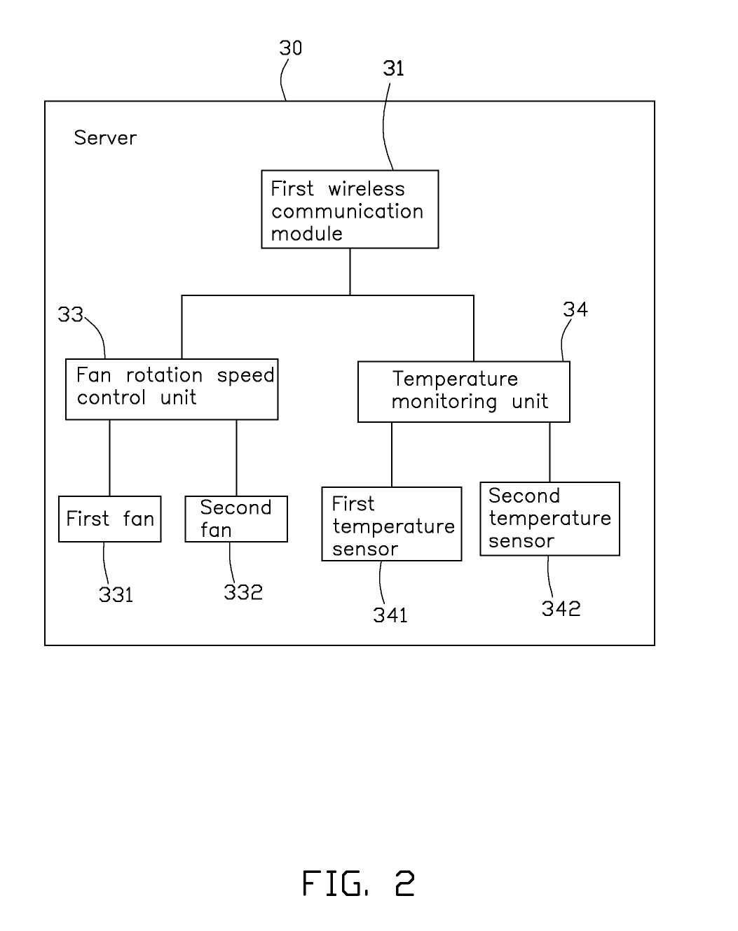

FIG. 2 shows each of the plurality of servers 30 includes a first wireless communication unit 31, a fan rotation speed control unit 33, a temperature monitoring unit 34, a first fan 331, a second fan 332, a first temperature sensor 341, and a second temperature sensor 342. The first fan 331 and the second fan 332 are used to dissipate heat from a server. In one embodiment, the first fan 331 is mounted on a front portion of the server, and the second fan 332 is mounted on a second rear portion of the server. The first temperature sensor 341 is located adjacent the first fan 331 to sense a first temperature. The second temperature sensor 342 is located adjacent the second fan 332 to sense a second temperature.

The first wireless communication 31 is connected to the fan rotation speed control unit 33 and the temperature monitoring unit 34. The temperature monitoring unit 34 is connected to the first temperature sensor 341 and the second temperature sensor 342. The first temperature sensor 341 senses the first temperature to generate a first temperature signal. The second temperature sensor 342 senses the second temperature generating a second temperature signal. The temperature monitoring unit 34 receives the first temperature signal and the second temperature signal. The fan rotation speed control unit 33 monitors a rotation speed of the first fan 331 generating a first fan rotation speed signal. The fan rotation speed control unit 33 monitors a rotation speed of the second fan 332 generating a second fan rotation speed signal. The fan rotation speed control unit 33 also can control rotation speed of the first fan 331 and the second fan 332.

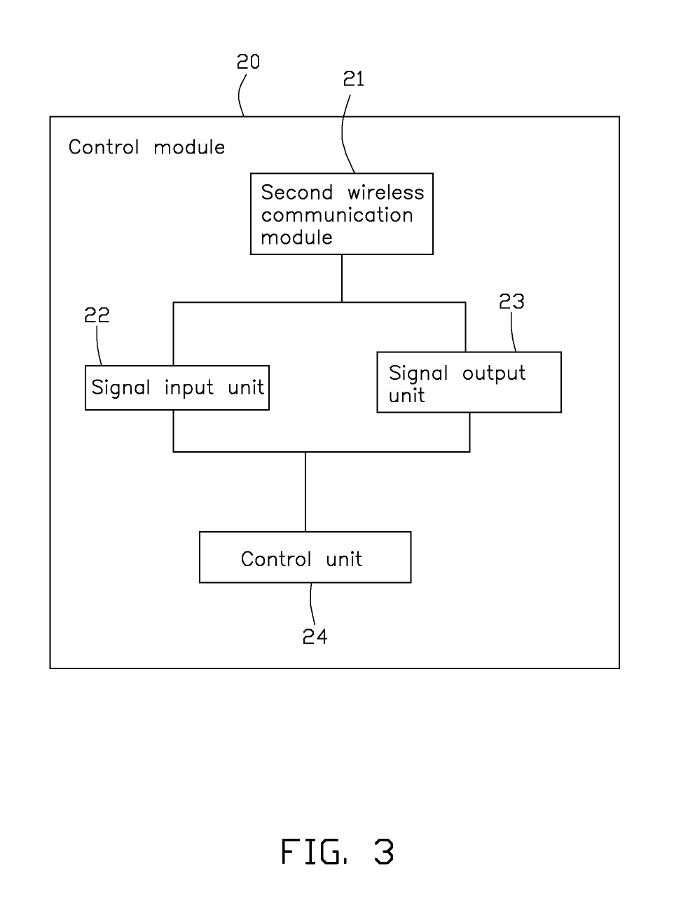

FIG. 3 shows the control module 20 includes a second wireless communication unit 21, a signal input unit 22, a signal output unit 23, and a control unit 24. The second wireless communication unit 21 can communicate with the first wireless communication unit 31 via wireless manner to transmit signals. The fan rotation speed control unit 33 can send the first and second fan rotation speed signals to the signal input unit 22 via the first and second wireless communication units 31 and 21. The temperature monitoring unit 34 can send the first and second temperature signals to the signal input unit 22 via the first and second wireless communication units 31 and 21. The signal input unit 22 inputs the first and second fan rotation speed signals and the first and second temperature signals to the control unit 24. The control unit 24 generates a first control signal based on the first fan rotation speed signal and the first temperature signal, and generates a second control signal based on the second fan rotation speed signal and the second temperature signal. The control unit 24 transmits the first and second control signals to the signal output units 23. The signal output unit 23 sends the first and second control signals to the fan rotation speed control unit 33 via the second wireless communication unit 21 and the first wireless communication unit 31. The fan rotation speed control unit 33 adjusts the rotation speed of the first fan 331 according to the first control signal, and adjusts the rotation speed of the second fan 332 according to the second control signal.

When the plurality of servers 30 operate, the control module 20 receives fan rotation speed signals and temperature signals of each of the plurality of servers 30. All of the fans of all of the plurality of servers 30 are controlled by the control module 20, which is efficient.

It is to be understood, however, that even though numerous characteristics and advantages of the embodiments have been set forth in the foregoing description, together with details of the structure and functions of the embodiments, the disclosure is illustrative only, and changes may be made in detail, especially in the matters of shape, size, and arrangement of parts within the principles of the invention to the full extent indicated by the broad general meaning of the terms in which the appended claims are expressed.

What is claimed is:

1. A managing system for dissipating heat from a plurality of servers, comprising:
a first wireless communication unit, a fan rotation speed control unit, a first fan, and a first temperature sensor located in each of the plurality of servers, the fan rotation speed control unit and the first temperature sensor being connected to the first wireless communication unit, the fan rotation speed control unit being connected to the first fan, the fan rotation speed control unit being adapted to monitor a rotation speed of the first fan and to generate a first fan rotation speed signal, the first temperature sensor being adapted to sense a temperature and to generate a first temperature signal; and
a control module comprising a second wireless communication unit and a control unit, the control unit being adapted to receive the first fan rotation speed signal and the first temperature signal via the first wireless communication unit and the second wireless communication unit, the control unit being adapted to generate a first control signal based on the first fan rotation speed signal and the first temperature signal, the fan rotation speed control unit being adapted to adjust the rotation speed of the first fan according to the first control signal.

2. The managing system of claim 1, wherein the control module comprises a signal input unit which is connected between the second wireless communication unit and the control unit, and the signal input unit is adapted to input the first fan rotation speed signal and the first temperature signal into the control unit.

3. The managing system of claim 2, wherein the control module comprises a signal output unit which is connected between the second wireless communication unit and the control unit, and the signal output unit is adapted to output the first control signal to the fan rotation speed control unit from the control unit.

4. The managing system of claim 1, wherein the first temperature sensor is located adjacent the first fan.

5. The managing system of claim 1, further comprising a second fan and a second temperature sensor located in each of the plurality of servers, wherein the first temperature sensor is located adjacent the first fan, the second temperature sensor is located adjacent the second fan, the second temperature sensor generates a second temperature signal, and the fan rotation speed control unit is adapted to monitor a rotation speed of the second fan and to generate a second fan rotation speed signal.

6. The managing system of claim 5, wherein the control unit is adapted to receive the second fan rotation speed signal and the second temperature signal via the first wireless communication unit and the second wireless communication unit, the control unit is adapted to generate a second control signal based on the second fan rotation speed signal and the second temperature signal, and the fan rotation speed control unit is adapted to adjust the rotation speed of the second fan according to the second control signal.

7. The managing system of claim 5, wherein the first fan is placed on a front portion of each of the plurality of servers, and the second fan is placed on a rear portion of each of the plurality of servers.

8. A managing system, comprising:
a plurality of servers, each of the plurality of servers comprising a fan rotation speed control unit, a first fan, and a temperature monitoring unit, the fan rotation speed control unit being adapted to monitor a rotation speed of the first fan and to generate a first fan rotation speed signal, the temperature monitoring unit being adapted to monitor temperature of corresponding server and to generate a temperature signal; and
a control module comprising a control unit, the control unit being adapted to generate a first control signal based on the first fan rotation speed signal and the temperature signal, and the fan rotation speed control unit being adapted to adjust the rotation speed of the first fan according to the first control signal.

9. The managing system of claim 8, wherein the temperature monitoring unit comprises a first temperature sensor which is located adjacent to the first fan, the first temperature sensor is adapted to sense a temperature and to generate a first temperature signal.

10. The managing system of claim 9, further comprising a second fan located in each of the plurality of servers, wherein the temperature monitoring unit comprises a second temperature sensor which is located adjacent to the second fan, the second temperature sensor is adapted to sense a temperature and to generate a second temperature signal, and the fan rotation speed control unit is adapted to monitor a rotation speed of the second fan and to generate a second fan rotation speed signal.

11. The managing system of claim 10, wherein the control unit is adapted to receive the second fan rotation speed signal and the second temperature signal, the control unit is adapted to generate a second control signal based on the second fan rotation speed signal and the second temperature signal, and the fan rotation speed control unit is adapted to adjust the rotation speed of the second fan according to the second control signal.

12. The managing system of claim 10, wherein the first fan is placed on a front portion of each of the plurality of servers, and the second fan is placed on a rear portion of each of the plurality of servers.

13. The managing system of claim 8, further comprising a first wireless communication unit in each of the plurality of servers, wherein the control module comprises a second wireless communication unit, the control unit is connected to the second wireless communication unit, the fan rotation speed control unit and the temperature monitoring unit are connected to the first wireless communication unit, and the control module is adapted to communicate with each of the plurality of servers via the first wireless communication unit and the second wireless communication unit.

14. The managing system of claim 13, wherein the control module comprises a signal input unit which is connected between the second wireless communication unit and the control unit, and the signal input unit is adapted to input the first fan rotation speed signal and the first temperature signal into the control unit.

15. The managing system of claim 14, wherein the control module comprises a signal output unit which is connected between the second wireless communication unit and the control unit, and the signal output unit is adapted to output the first control signal to the fan rotation speed control unit from the control unit.
